(19) United States
(12) Patent Application Publication
(10) Pub. No.: US 2024/0147616 A1
(43) Pub. Date: May 2, 2024

(54) ELECTRONIC DEVICE ASSEMBLY APPARATUS

(71) Applicant: NACHI-FUJIKOSHI CORP., Tokyo (JP)

(72) Inventors: Akira KUNISAKI, Toyama (JP); Shun SASAKI, Toyama (JP)

(73) Assignee: NACHI-FUJIKOSHI CORP., Tokyo (JP)

(21) Appl. No.: 18/496,935

(22) Filed: Oct. 30, 2023

(30) Foreign Application Priority Data
Oct. 31, 2022 (JP) 2022-174856

(51) Int. Cl. H05K 1/03; H05K 13/00; H05K 13/04

(52) U.S. Cl. CPC H05K 1/0393; H05K 13/0015; H05K 13/0408; H05K 13/046; H05K 2201/10356

(57) ABSTRACT

In an electronic device assembly apparatus that inserts a leading end of flat and flexible cables 162 and 166 into connectors 164 and 168 on a circuit board 160, a gripping device 200 includes a first gripping mechanism 210 and a second gripping mechanism 212, a rotational mechanism 260, and a width direction open/close mechanism 240, and the width direction open/close mechanism 240 includes a first cylinder 244 and a second cylinder 270 that causes the first and the second gripping mechanism to perform a width adjustment movement in the same direction as the first cylinder, and the second cylinder has a lock function for fixing the second cylinder at a predetermined position.

This application is based upon and claims the benefit of priority from the prior Japanese Patent Application No. 2022-174856, filed on Oct. 31, 2022, the entire contents of which are incorporated herein by reference.

### BACKGROUND OF INVENTION

### 1. Field of the Invention

The present invention relates to an electronic device assembly apparatus that grips a cable connected to a circuit board of an electronic device or the like.

### 2. Description of Related Art

An electronic device assembly apparatus is a device that is used at a production site such as a plant and connects a leading end of a cable such as an FPC (Flexible Printed Circuit) and an FFC (Flexible Flat Cable) to a connector on a circuit board. A cable such as an FPC is thin, flat, and flexible. Such a cable cannot be gripped by a regular robotic hand (fingers). For example, an electronic device assembly apparatus disclosed in Japanese Patent No. 6500247 includes a chuck for deciding a position in a width direction of a leading end of a cable, and a cable suction portion that suctions and holds the leading end of the cable by suctioning the surface thereof.

However, there are cases in which the holding force by suction is not sufficient. In such cases, when the leading end of the cable is brought into contact with a connector, the cable may retract or be obliquely inclined.

Also, conventional electronic device assembly apparatuses can handle only connectors with the same width. As such, when wiring a plurality of types of cables, a plurality of hands need to be mounted on a robot, or the hands need to be changed using a hand changing device or the like.

If a plurality of hands are mounted on a robot, there is a problem that because of an increase in weight of the hands, a robot with greater payload capacity needs to be used, resulting in increased space requirements and cost. If the hands are changed, there is a problem that the time for changing the hands and a space for placing the hands of different types are required.

In view of such problems, the present invention aims to provide an electronic device assembly apparatus capable of dramatically increasing a force for holding a cable and performing connection work for connecting a plurality of types of cables having different widths.

### SUMMARY OF THE INVENTION

a representative configuration of the present invention is an electronic device assembly apparatus for inserting insert a leading end of a flat and flexible cable into a connector on a circuit board, the electronic device assembly apparatus including a gripping device that grips the cable, and a robot arm that moves the gripping device, and the gripping device includes a first gripping mechanism that includes a pair of claws that grip, in a thickness direction, one lateral side of the cable, a second gripping mechanism that includes a pair of claws that grip, in the thickness direction, the other lateral side of the cable, and a width direction open/close mechanism that opens/closes the first gripping mechanism and the second gripping mechanism in a cable width direction, the width direction open/close mechanism includes a first cylinder that causes at least one of the first gripping mechanism and the second gripping mechanism to perform a gripping movement for gripping and releasing, in a direction of advancing and retracting with respect to the lateral sides of the cable, and a second cylinder that causes at least the first gripping mechanism and the second gripping mechanism to perform a width adjustment movement for aligning a stroke range of the gripping movement with a difference in cable width, in the same direction as the first cylinder, and the second cylinder has a lock function for fixing the second cylinder at a predetermined position.

### BRIEF DESCRIPTION OF THE DRAWINGS

FIG. 1 is a perspective view showing an overall configuration of an electronic device assembly apparatus according to an embodiment of the present invention.

FIG. 2A is a front view of a gripping device in FIG. 1.

FIG. 2B is a side view of the gripping device in FIG. 1.

FIG. 3A is a diagram showing a state in which a second claw is open (retracted).

FIG. 3B is a diagram showing a state in which the second claw is closed (advanced).

FIG. 4 is a perspective view illustrating a first claw in FIG. 3.

FIG. 5A is a diagram illustrating a width direction open/close mechanism of a first gripping mechanism and a second gripping mechanism.

FIG. 5B is a diagram illustrating a gripping movement.

FIG. 5C is a diagram illustrating a width adjustment movement.

FIG. 6 is a diagram illustrating a rotation mechanism of the first gripping mechanism and the second gripping mechanism.

FIG. 7A is a front view of a gripping device according to another embodiment.

FIG. 7B is a side view of the gripping device according to the other embodiment.

FIG. 8A is a front view of a gripping device according to another embodiment.

FIG. 8B is a top view of the gripping device according to the other embodiment.

FIG. 9 is a diagram illustrating a gripping mechanism of the gripping device shown in FIG. 8A.

FIG. 10A is an enlarged view showing a region of a rotational shaft in FIG. 9.

FIG. 10B shows an example in which only an outer circumferential groove is provided and no inner circumferential groove is provided.

FIG. 10C shows an example in which only an inner circumferential groove is provided and no outer circumferential groove is provided.

FIG. 10D shows an example in which two systems, i.e., outward paths and return paths are formed in the rotational shaft.

FIG. 11 is a diagram showing another embodiment of the gripping device shown in FIG. 6.

FIG. 12 is a diagram showing another embodiment of the gripping device shown in FIG. 6.

### DETAILED DESCRIPTION OF PREFERRED EMBODIMENT

Preferred embodiments of the present invention will be described in detail below with reference to the accompanying drawings. The dimensions, materials, and other specific numerical values shown in the embodiments are merely examples for facilitating the understanding of the invention, and are not intended to limit the present invention unless otherwise specified. Note that in the present specification and drawings, elements having substantially the same function and configuration are designated by the same reference signs in order to omit redundant descriptions, and elements not directly related to the present invention are not shown.

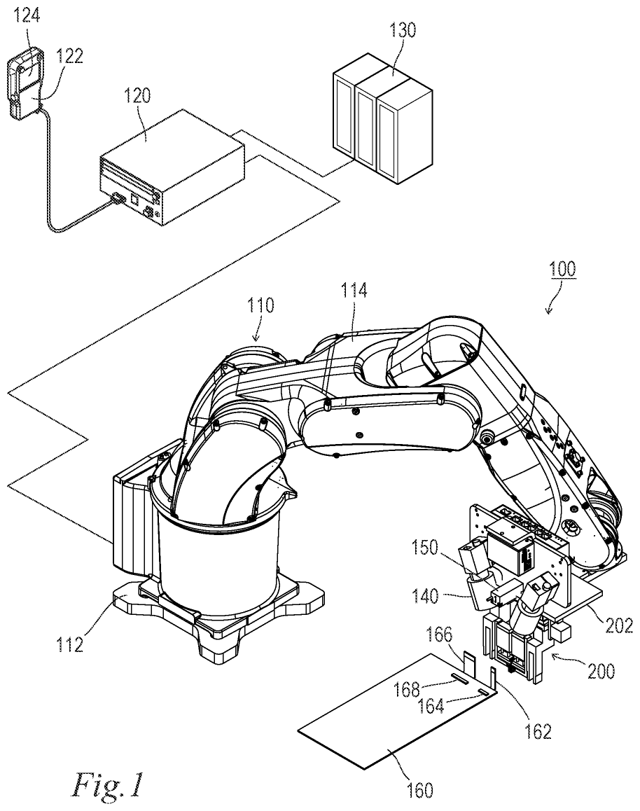

FIG. 1 is a perspective view showing an overall configuration of an electronic device assembly apparatus 100 according to an embodiment of the present invention. The electronic device assembly apparatus 100 is, for example, a device that is used at a production site such as a plant, grips a plurality of types of cables 162 and 166 having different widths with a gripping device 200, and connects the cables to connectors 164 and 168 of a circuit board 160, which is the connection destination. The cables 162 and 166 are flat, long, and flexible cables such as FPCs or FFCs.

The electronic device assembly apparatus 100 includes a robot body 110 shown in FIG. 1 and a robot control device 120 connected to the robot body 110. The robot body 110 includes a base portion 112, a robot arm 114 supported by the base portion 112, and a gripping device 200 serving as a manipulator. The robot arm 114 may be, for example, a six-axis or five-axis vertical articulated robot or a horizontal articulated robot.

An input device 122, a state notification device 124, and an upper-level control system 130 are connected to the robot control device 120. The input device 122 is a device that inputs commands, parameters, and the like to the robot control device 120. The state notification device 124 is a device that receives and displays an operation state of the robot body 110, a state of connection work, and the like that are transmitted from the robot control device 120.

The upper-level control system 130 is constituted by, for example, a sequencer (PLC), a monitoring and control system (SCADA), a process computer (PROCOM), a personal computer, various servers, or a combination thereof, and connected to the robot control device 120 wirelessly or by cable. The upper-level control system 130 outputs instructions based on the operation states of the devices that constitute a production line including the robot control device 120, and comprehensively controls the production line.

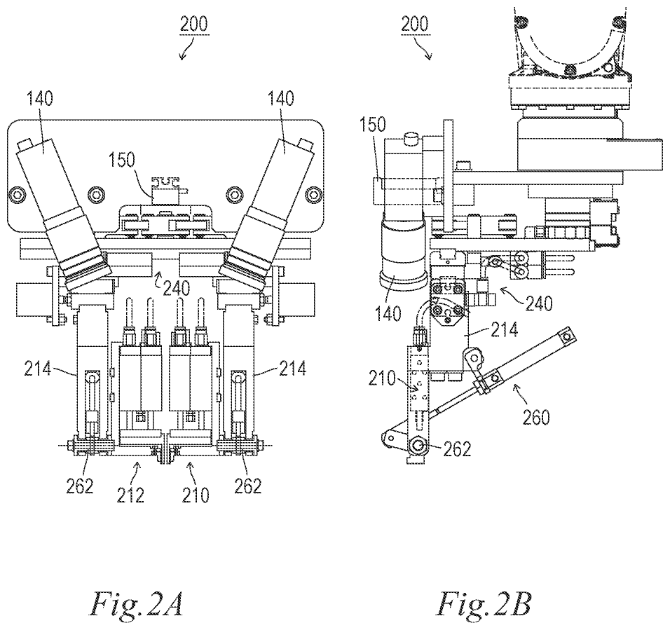

FIG. 2A is a front view of the gripping device 200 in FIG. 1, and FIG. 2B is a side view of the gripping device 200 in FIG. 1. The gripping device 200 includes cameras 140, a light 150, and a first gripping mechanism 210 and a second gripping mechanism 212 that respectively grip the leading ends of the cables 162 and 166. The robot control device 120 performs visual feedback control based on video captured by the cameras 140, and grips and inserts the leading ends of the cables 162 and 166 into the connectors 164 and 168, respectively. At least one camera 140 is required, but provision of two or more cameras 140 is preferable because image capturing accuracy is improved. The cameras 140 may also obtain color images or monochrome images. Note that, operation control of the gripping device 200 may be performed using a system control device (e.g., a control device in which a PLC is used) instead of the robot control device 120.

As described later, the first gripping mechanism 210 grips one lateral side of a portion near the leading end of the cable in the thickness direction, and the second gripping mechanism 212 grips the other lateral side of a portion near the leading end of the cable in the thickness direction.

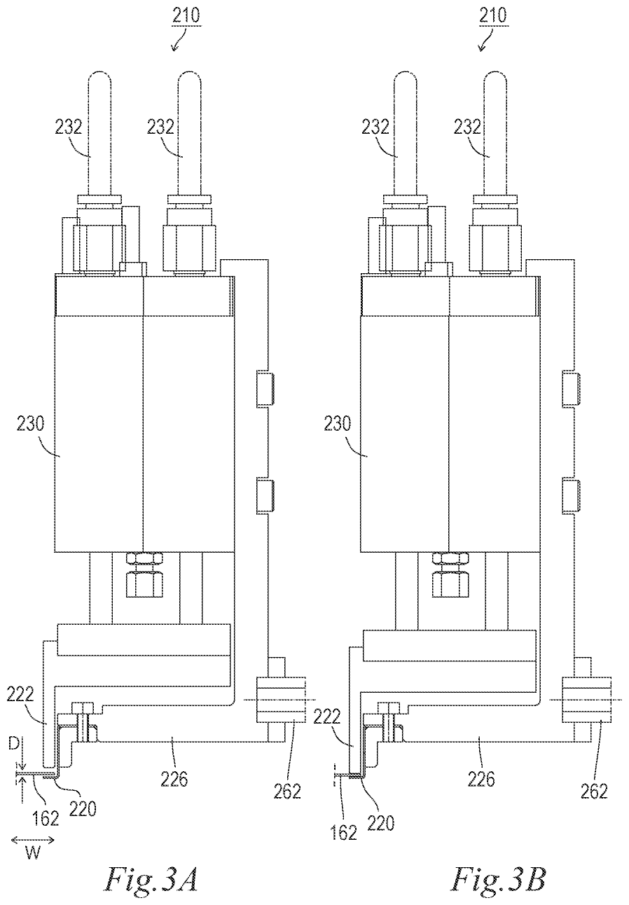

FIG. 3A shows a state in which the second claw 222 is open (retracted), and FIG. 3B shows a state in which the second claw 222 is closed (advanced). Since the second gripping mechanism 212 is bilaterally symmetrical to the first gripping mechanism 210, the second gripping mechanism 212 is not shown in FIGS. 3A and 3B.

The first gripping mechanism 210 includes a first claw 220 (the lower claw in the drawing) and a second claw 222 (the upper claw in the drawing) as a pair of claws that grip the lateral side of the cable 162 in a thickness direction D. The first claw 220 is located on the circuit board 160 side when gripping the cable 162 and inserting the cable 162 into the connector 164. The second claw 222 is located on the opposite side to the circuit board 160 with respect to the cable 162 that is gripped.

The first claw 220 is fixed to a bracket 226. In contrast, the second claw 222 advances toward and retracts from the first claw 220 with use of a gripping air cylinder 230. Air used when advancing and retracting is supplied to the gripping air cylinder 230 via an air tube 232. With this, the lateral side of the cable 162 is pinched between the first claw 220 and the second claw 222. FIG. 3A shows a state in which the second claw 222 is open (retracted), and FIG. 3B shows a state in which the second claw 222 is closed (advanced).

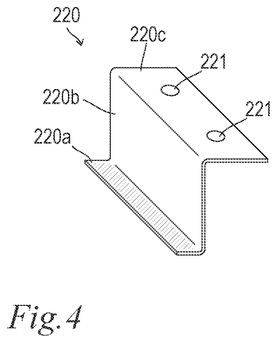

FIG. 4 is a perspective view illustrating the first claw 220 in FIG. 3. The first claw 220 is formed by a metal plate member (spring steel), and has elasticity and high rigidity. In the present embodiment, the first claw 220 is formed by being bent in a crank shape to have three surfaces, namely, a pinching face 220a, a standing face 220b, and a fixing face 220c provided with bolt holes 221. In this manner, an elastic region that is deformed when a load is applied to the pinching face 220a is increased in size.

The first gripping mechanism 210 and the second gripping mechanism 212 grip the cables 162 and 166 in the thickness direction D. By doing so, the holding force can be dramatically increased compared to the conventional case in which the cables 162 and 166 are gripped in the width direction W and suctioned by air. Also, by applying coating processing or surface processing which increases the friction coefficient on the pinching face 220a (the hatched portion in FIG. 4) that is a face of the first claw 220 on the second claw 222 side, the holding force can be further increased. Examples of coating processing include rubber lining, polyurethane coating, silicone coating, and metallic spraying. In addition, examples of surface processing include increasing the surface roughness by sand blasting or chemical processing.

Also, according to the above configuration, when inserting the cables 162 and 166 into the connectors 164 and 168, the space required on the circuit board 160 side with respect to the cables 162 and 166 can be set to the thickness of the first claw 220. Accordingly, the cables 162 and 166 can be brought close to the circuit board 160, and the leading ends of the cables 162 and 166 can be easily inserted into the connectors 164 and 168, whose height has decreased in recent years.

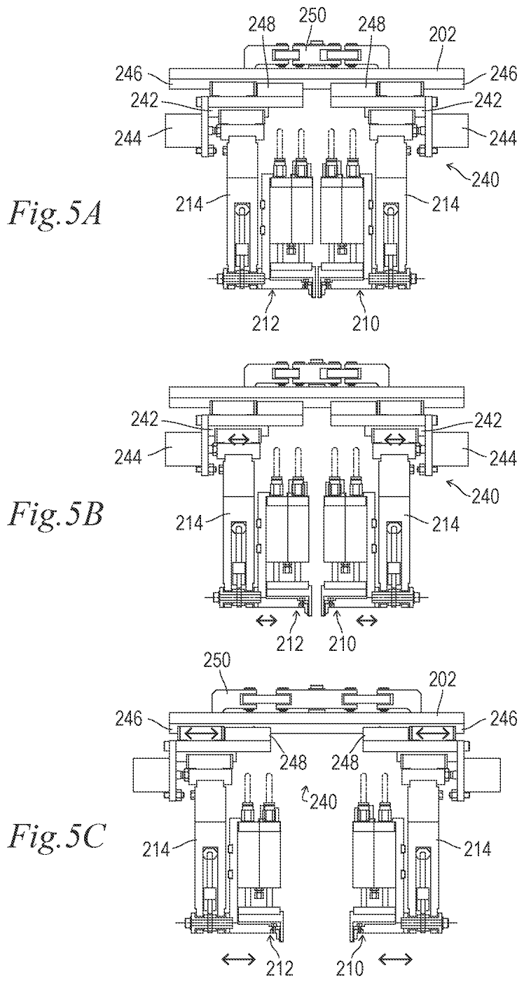

FIG. 5A is a diagram illustrating a width direction open/close mechanism 240 of the first gripping mechanism 210 and the second gripping mechanism 212. The width direction open/close mechanism 240 performs two types of movements. The first type is movement for gripping and releasing the cables 162 and 166 (movement from the gripping position to a width sufficient for the first claw 220 to avoid the lateral sides of the cables 162 and 166). In the following description, the first type of movement is referred to as a “gripping movement”. The second type is movement for aligning the stroke range of the gripping movement with the difference in the widths of the cables 162 and 166. In the following description, the second type of movement will be referred to as a “width adjustment movement”. Generally, the stroke of the gripping movement is smaller and the stroke of the width adjustment movement is larger, but either type of movement may have the larger stroke, depending on the design concept.

As shown in FIG. 5A, the width direction open/close mechanism 240 is constituted by first linear motion guides 242, first cylinders 244, and a second linear motion guides 246. The first gripping mechanism 210 and the second gripping mechanism 212 are respectively supported by side plates 214. The side plates 214 are slidably supported by the first linear motion guides 242 and is movable by the first cylinders 244 (air cylinders) that move the first gripping mechanism 210 and the second gripping mechanism 212 in the direction of advancing toward and retracting from the lateral sides of the cables. As shown in FIG. 5B, the gripping movement is performed by the first linear motion guides 242 and the first cylinders 244.

Note that in the present embodiment, two first cylinders 244 can respectively move the first gripping mechanism 210 and the second gripping mechanism 212. However, only one of the first gripping mechanism 210 and the second gripping mechanism 212 may be moved in the width direction to grip the cables. In that case, one first cylinder may move either the first gripping mechanism 210 or the second gripping mechanism 212.

Further, the first linear motion guides 242 are slidably supported by the second linear motion guides 246 attached to a base 202 of the gripping device 200 and can be fixed at a desired position with lock mechanisms 248. Various members can be used for the lock mechanisms 248. For example, normally closed linear clamps which are normally clamped with springs and are released by supplied air can be used. Note that in the first linear motion guides 242, the lateral movement amounts thereof are set to match by link mechanisms 250 of the second linear motion guides 246 attached to the base 202 of the gripping device 200. With these second linear motion guides 246 and the lock mechanism 248, the width adjustment movement is performed, as shown in FIG. 5C. In this manner, the gripping device 200 can hold a plurality of types of cables 162 and 166 having different width dimensions.

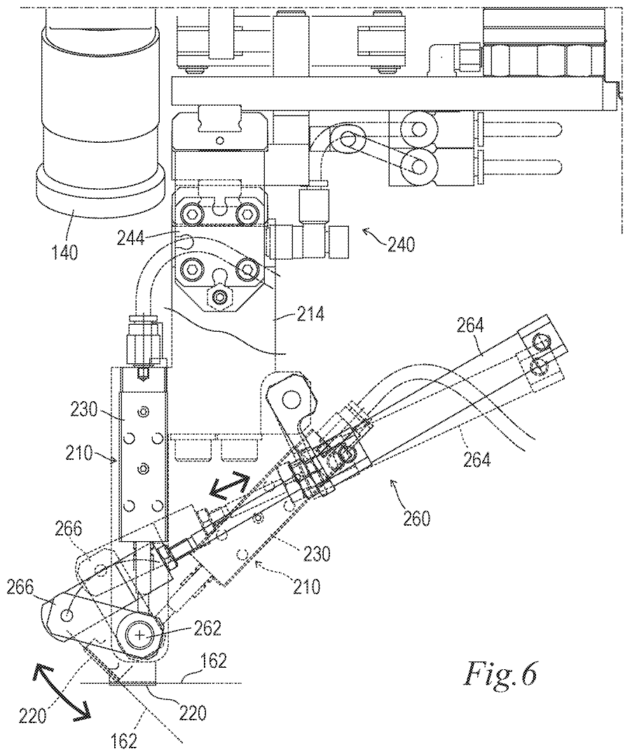

FIG. 6 is a diagram illustrating a rotation mechanism 260 of the first gripping mechanism 210 and the second gripping mechanism 212. FIG. 6 will be described taking the first gripping mechanism 210 as an example. Since the second gripping mechanism 212 is bilaterally symmetrical to the first gripping mechanism 210, the second gripping mechanism 212 is not shown in FIG. 6.

The bracket 226 of the first gripping mechanism 210 is connected to the side plate 214 by the rotational shaft 262 (see also FIGS. 2 and 3). The side plate 214 includes a rotation cylinder 264. The rotation cylinder 264 is connected to the rotational shaft 262 via a link 266. With this configuration, when the rotation cylinder 264 extends and retracts, the first gripping mechanism 210 rotates in the direction in which the cables 162 and 166 bend via the link 266 and the rotational shaft 262. Accordingly, when gripping the cables 162 and 166, the angle of the first claw 220 and the second claw 222 can be changed in accordance with the angle of the cables 162 and 166, which makes it possible to smoothly grip the cables 162 and 166.

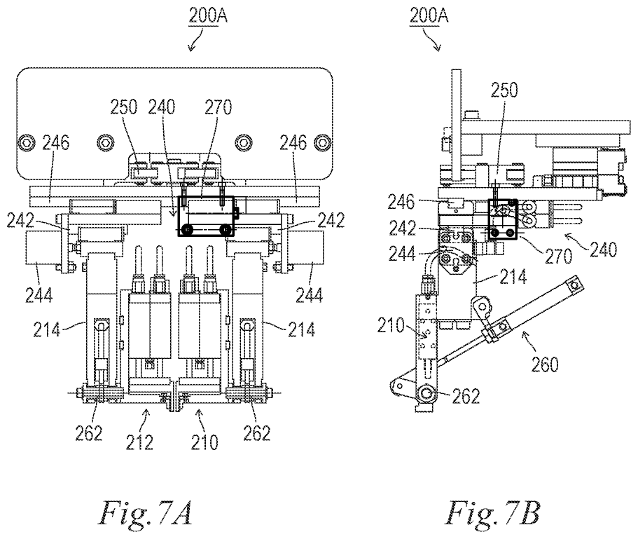

FIG. 7A is a front view of the gripping device 200A according to another embodiment, and FIG. 7B is a side view of the gripping device 200A according to the other embodiment. Portions that are redundant with the above description are given the same reference signs and the description thereof will be omitted. Also, in FIG. 7, the cameras 140 and the light 150 are not shown.

In the configuration shown in FIG. 7, the width direction open/close mechanism 240 includes the first cylinders 244 that perform the gripping movement and a second cylinder 270 that performs the width adjustment movement. The second cylinder 270 moves the two first linear motion guides 242 (indirectly, the first gripping mechanism 210 and the second gripping mechanism 212) along the second direction motion guide 246 in the same direction as the first cylinders 244. Although only one second cylinder 270 is provided in FIG. 7, the left and right first direct motion guides 242 operate together in opposite directions through the link mechanism 250. The second cylinder 270 adjusts the interval between the first gripping mechanism 210 and the second gripping mechanism 212 in accordance with the widths of the cables 162 and 166. Generally, the stroke of gripping movement is smaller and the stroke of the width adjustment movement is larger. However, either type of movement may have the larger stroke, depending on the design concept.

Note that, although both the left and right first linear motion guides 242 (i.e., the first gripping mechanism 210 and the second gripping mechanism 212) are moved with use of the link mechanism 250 in the present embodiment, the width adjustment movement may be performed by moving only one of the left and right first linear motion guides 242 in the width direction.

The second cylinder 270 for the width adjustment movement has a lock function for fixing the second cylinder 270 at a predetermined position. With this, displacement of the first linear motion guides 242 at the time of operation of the first cylinders 244 can be prevented. Note that a lock mechanism may also be provided to the first cylinders 244 for performing the gripping movement. With this, the gripping force can be further strengthened.

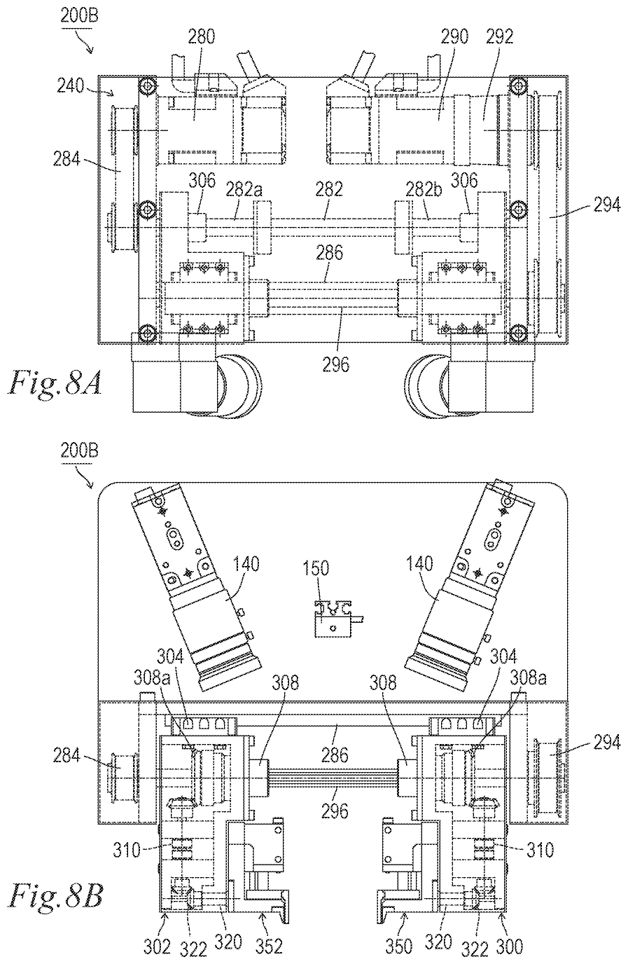

FIG. 8A is a front view of a gripping device 200B according to another embodiment, and FIG. 8B is a front view of the gripping device 200B according to the other embodiment. Portions that are redundant with the above description are given the same reference signs and the description thereof will be omitted.

As shown in FIG. 8A, the gripping device 200B is provided with an open/close servo motor 280 and a turn buckle shaft 282 serving as the width direction open-close mechanism 240, instead of the first cylinders 244 and the second cylinder 270 (see FIG. 7). The turn buckle shaft 282 is a shaft having a right screw 282a (positive screw) at one end, and a left screw 282b (reverse screw) at the other end. The open/close servo motor 280 and the turn buckle shaft 282 are connected via a timing belt 284. Note that, a known drive transmission mechanism such as a shaft coupling and a gear train can be used instead of the timing belt 284.

As shown in FIG. 8B, the gripping device 200B includes one linear motion guide 286. A first block 300 that supports a first gripping mechanism 350 and a second block 302 that supports a second gripping mechanism 352 are slidably attached to the linear motion guide 286 through a slider 304. Also, the first block 300 and the second block 302 each include a shaft bearing 306 that is engaged with the turn buckle shaft 282. Accordingly, when the turn buckle shaft 282 is rotated by the open/close servo motor 280, the first block 300 and the second block 302 respectively move in opposite directions, and thus the space between the first gripping mechanism 350 and the second gripping mechanism 352 can be opened/closed. The width direction open/close mechanism 240 can perform both the gripping movement and the width adjustment movement.

Also, as the rotation mechanism, a rotation servo motor 290 is provided instead of the rotation cylinder 264 (see FIG. 6). In the rotation servo motor 290, drive is transmitted to a spline shaft 296 via a speed reducer 292 and a timing belt 294. Sleeves 308 of the first block 300 and the second block 302 are engaged with the spline shaft 296 (ball spline) so as to be slidable and rotationally drivable. Drive is transmitted from helical gears 308a of the sleeves 308 to helical gears 322 of the rotational shafts 320 of the first gripping mechanism 350 and the second gripping mechanism 352 via the gear trains 310. Accordingly, when the spline shaft 296 is rotated by the rotation servo motor 290, the first gripping mechanism 350 and the second gripping mechanism 352 can be rotated in the direction in which the cables 162 and 166 bend.

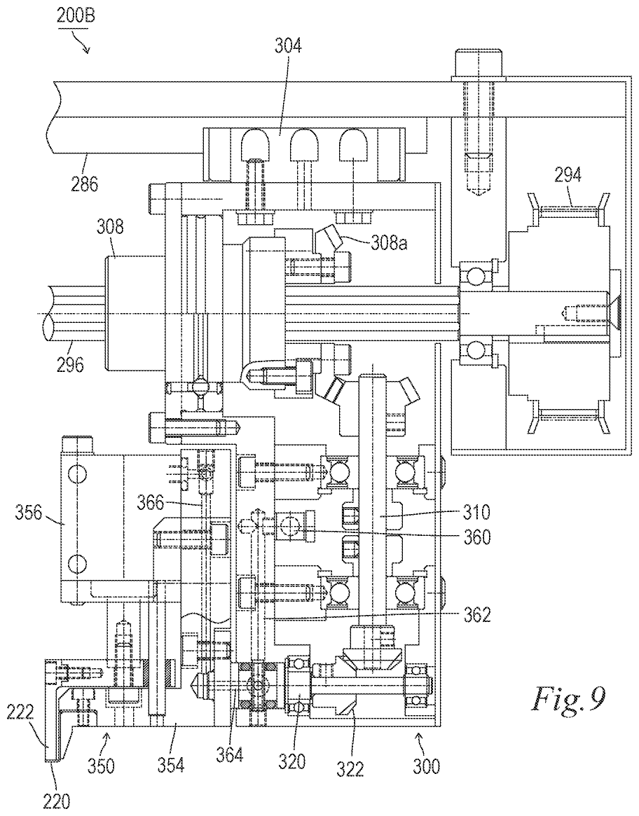

FIG. 9 is a diagram illustrating the gripping mechanism of the gripping device 200B in FIG. 8A. FIG. 9 will be described taking the first gripping mechanism 350 as an example. Since the second gripping mechanism 352 is bilaterally symmetrical to the first gripping mechanism 350, the second gripping mechanism 352 is not shown in FIG. 9.

As shown in FIG. 9, the first gripping mechanism 350 includes a gripping air cylinder 356. The gripping air cylinder 356 has no air tube that extends outward (see the air tube 232 in FIG. 3), and a flow path for supplying the air to the gripping air cylinder 356 is formed inside the rotational shaft 320.

Specifically, the first gripping mechanism 350 includes a port 360 for connecting the air tube (not shown) to the first block 300, and the air is supplied to the gripping air cylinder 356 via a first flow path 362 in the first block 300, a second flow path 364 in the rotational shaft 320, and a third flow path 366 in the bracket 354 of the first gripping mechanism 350.

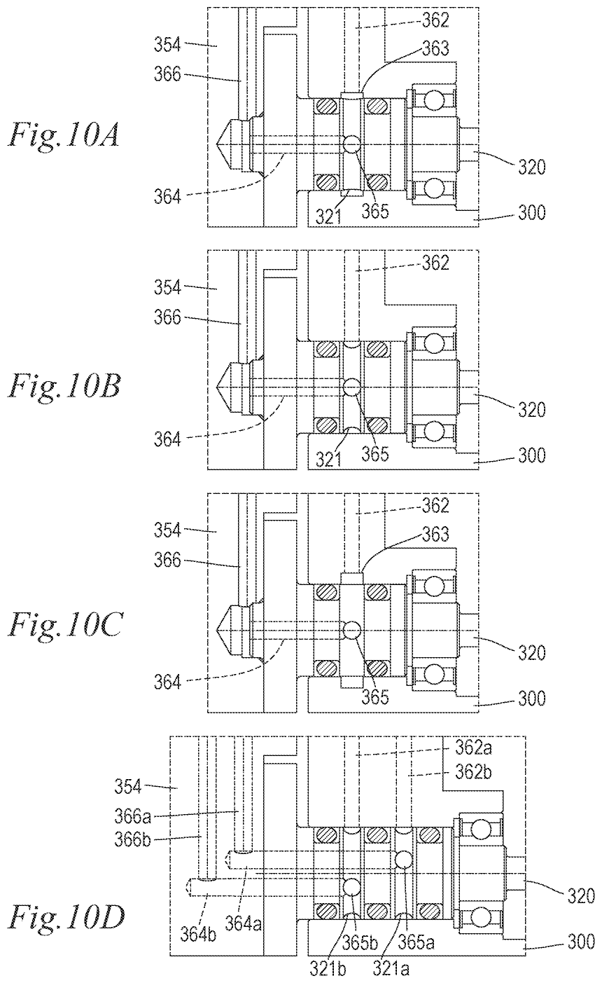

FIG. 10A is an enlarged view showing a region of the rotational shaft 320 in FIG. 9. The rotational shaft 320 is fixed to the bracket 354 and rotates as one piece. Accordingly, the air needs to be caused to flow from the first flow path 362 in the nonrotatable first block 300 to the second flow path 364 inside the rotatable rotational shaft 320.

In view of this, in the configuration in FIG. 10A, a hole 365 that is in communication with the second flow path 364 is formed in the outer circumference of the rotational shaft 320. Also, an outer circumferential groove 321 is formed at a position of a hole 365 in the outer circumference of the rotational shaft 320. In the first block 300, an inner circumference groove 363 is formed at a position that opposes the hole 365. In this manner, a circumferential flow path is formed by the outer circumferential groove 321 and the inner circumferential groove 363, and which makes it possible to cause the air to flow in the outer circumferential groove 321 regardless of the rotational phase of the rotational shaft 320.

The configuration shown in FIG. 10B is an example in which only the outer circumferential groove 321 is provided and no circumferential groove 363 is provided. The configuration shown in FIG. 10C is an example in which the inner circumferential groove 363 is provided and no outer circumferential groove 321 is provided.

Since only a single system supplies the air in the configuration shown in FIGS. 10A to 10C, a return spring needs to be used for the gripping air cylinder 356. In contrast, in the configuration shown in FIG. 10D, two systems, that is, outward paths and return paths are formed in the rotational shaft 320. Specifically, the configuration is formed by a system formed by a first flow path 362a, a second path 364a, and a third flow path 366a, and a system formed by a first flow path 362b, a second flow path 364b, and a third flow path 366b. Holes 365a, 365b, and outer circumferential grooves 321a, 321b are formed in the outer circumference of the rotational shafts 320.

As described above, since the flow path for supplying air to the gripping air cylinder 356 is formed inside the rotational shaft 320, an air tube that extends outward can be eliminated, making it possible to reduce the sizes of the first gripping mechanism 350 and the second gripping mechanism 352. Accordingly, when the cables 162 and 166 are connected, the region in which the gripping device 200B interferes with the peripheral devices can be reduced.

Also, according to the above configuration, the rotation of the first gripping mechanism 350 and the second gripping mechanism 352 is not restricted by the air tube. And thus, the first gripping mechanism 350 and the second gripping mechanism 352 can take any posture at any angle, and can also be rotated by 360° or more. Accordingly, it is also possible to grip the leading ends of the cables 162 and 166 that horizontally extend, bend them by 180°, and insert the leading ends into the connectors 164 and 168.

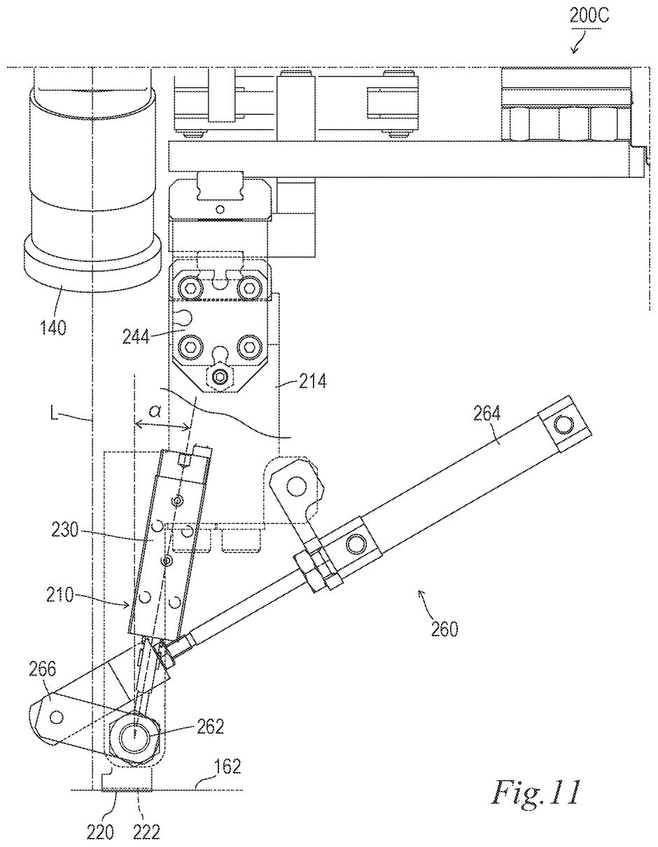

FIG. 11 is a diagram illustrating another embodiment of the gripping device shown in FIG. 6. Portions that are redundant with the description that has been given using FIGS. 1 to 6 are given the same reference signs and the description thereof will be omitted. In particular, compare FIG. 6. for reference purposes.

In a gripping device 200C shown in FIG. 11, the gripping air cylinder 230 is inclined by a predetermined angle α in a direction away from an optical axis V in a posture in which the optical axis V of the camera 140 is substantially vertical and the first claw 220 and the cable 162 are substantially horizontal. In this manner, the area in the field of view of the camera 140 in which the gripping air cylinder 230 enter can be reduced, and the leading end of the cable 162 can be easily observed. In particular, when the width of the cable 162 is narrow, the leading end of the cable 162 is likely to be hidden behind the gripping air cylinder 230. As such, it is highly advantageous to incline the gripping air cylinder 230.

Note that, since the gripping air cylinder 230 is inclined by a predetermined angle α, the second claw 222 is inclined by the predetermined angle α and pressed against the pinching face 220a (see FIG. 4) of the first claw 220. When the predetermined angle α is large, the cable may slip while being gripped, and thus it is preferable that the predetermined angle α is 10° or less.

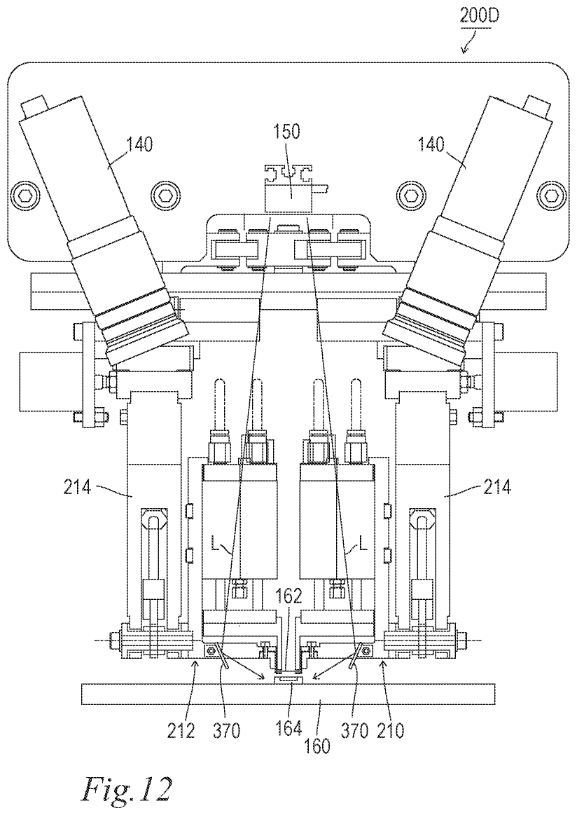

FIG. 12 is a diagram illustrating another embodiment of the gripping device shown in FIG. 6. Portions that are redundant with the description that has been given using FIGS. 1 to 6 are given the same reference signs and the description thereof will be omitted. In particular, compare FIG. 2A for reference purposes.

The first gripping mechanism 210 and the second gripping mechanism 212 of a gripping device 200D shown in FIG. 12 each include a reflection member 370 that reflects irradiation light L from the light 150 toward a side face of the cable 162. In this manner, when the leading end of the cable 162 is inserted into the connector 164, the lateral sides of the cable 162 and the side faces of the connector 164 can be illuminated.

In the state where the cable 162 and the connector 164 are illuminated with only light from the light 150 disposed directly above the cable 162, the shadow of the cable 162 may be cast on the circuit board 160, resulting in that the outline of the shadow being mistaken for the outline of the cable 162. Similarly, the outline of the shadow of the connector 164 may be mistaken for the outline of the connector 164. However, the shadow can be eliminated by illuminating from the side with the reflection member 370, such misrecognition can be prevented, and more accurate visual feedback control can be performed.

While preferred embodiments of the present invention have been described with reference to the attached drawings, it goes without saying that the present invention is not limited to these embodiments and examples. It is clear that those skilled in the art will be able to arrive at various changes and modifications within the scope of the claims, and those changes and modifications are understood to naturally fall within the technical range of the present invention.

1. An electronic device assembly apparatus for inserting insert a leading end of a flat and flexible cable into a connector on a circuit board, the electronic device assembly apparatus comprising:
a gripping device that holds the cable; and
a robot arm that moves the gripping device,
wherein the gripping device includes:
a first gripping mechanism that includes a pair of claws that hold, in a thickness direction, one lateral side of the cable;
a second gripping mechanism that includes a pair of claws that hold, in the thickness direction, the other lateral side of the cable; and
a width direction open/close mechanism that opens/closes the first gripping mechanism and the second gripping mechanism in a cable width direction,
the width direction open/close mechanism includes:
a first cylinder that causes at least one of the first gripping mechanism and the second gripping mechanism to perform a gripping movement for gripping and releasing, in a direction of advancing and retracting with respect to the lateral sides of the cable; and
a second cylinder that causes at least the first gripping mechanism and the second gripping mechanism to perform a width adjustment movement for aligning a stroke range of the gripping movement with a difference in cable width, in the same direction as the first cylinder, and
the second cylinder has a lock function for fixing the second cylinder at a predetermined position.
